(19) United States
(12) Patent Application Publication
(10) Pub. No.: US 2026/0141943 A1
(43) Pub. Date: May 21, 2026

(54) REFERENCE VOLTAGE OUTPUT CIRCUIT

(71) Applicant: INNOGRIT TECHNOLOGIES CO., LTD., Shanghai (CN)

(72) Inventors: Nannan YU, Shanghai (CN); Xiuli XU, Shanghai (CN); Lei JIANG, Shanghai (CN); Yongxu WANG, Shanghai (CN)

(21) Appl. No.: 19/388,570

(22) Filed: Nov. 13, 2025

(30) Foreign Application Priority Data
Nov. 15, 2024 (CN) 202411636623.8

(51) Int. Cl. G11C 11/4072; H03F 3/213; H03K 19/173; H03M 1/36

(52) U.S. Cl. CPC G11C 11/4072; H03F 3/213; H03K 19/1737; H03M 1/365

(57) ABSTRACT

This application relates to the field of electronic technology and discloses a reference voltage output circuit, comprising: a digital to analog converter comprising a resistor string divider, a first multiplexer and a second multiplexer, generating multiple bits of divided voltages that are grouped and output to respective first multiplexers; a level shift circuit that boosts the divided voltage output by the digital to analog converter in a low power mode; a selection module comprising a third multiplexer, receiving the boosted divided voltage output by the level shift circuit or the divided voltage output by the digital to analog converter, and based on the mode selection signal, selecting the boosted divided voltage for differential output in the low power mode or selects the divided voltage output by the digital to analog converter for differential output in a non-low power mode; an output buffer comprising a bias circuit, an operational amplifier, and an output stage circuit, the operational amplifier receives the differential voltages output by the selection module and amplifies the differential voltages, the output stage circuit converts the amplified differential voltages into a single ended voltage and outputs it as a reference voltage. The present invention can provide a reference voltage that is simultaneously universally applicable to different standards.

### CROSS-REFERENCE TO PRIOR APPLICATION

This application claims priority to Chinese Application No. 202411636623.8 filed on Nov. 15, 2024, which is incorporated herein by reference in its entirety.

### TECHNICAL FIELD

This application relates to the field of electronic technology, particularly to a reference voltage output circuit.

### BACKGROUND

When a device with a DRAM (Dynamic Random Access Memory) subsystem is powered on, or when a device with a NAND physical layer controller (PHY Controller) or a DDR (Double Data Rate Synchronous Dynamic Random Access Memory) physical layer controller subsystem is powered on, a series of initialization operations are required before the subsystem reaches an operable state. According to state machines described in the Joint Electron Device Engineering Council (JEDEC) specification, the initialization process that the subsystem goes through from power on to the operable state can be simply classified into four different stages: 1. power on and initialization; 2. ZQ calibration (Zero Quiet Calibration); 3. reference voltage (VREF DQ, or simply VREF) calibration; 4. read and write training.

The present invention mainly relates to the VREF calibration process, which refers to the process of calibrating the reference voltage in the memory module to ensure an accurate reference voltage for the signal level during data transmission, optimize electrical characteristics of signal transmission, reduce signal noise and interference, and thus improve the accuracy and reliability of data transmission.

VREF calibration typically involves setting voltage range and step size (1LSB) of the VREF, and adjusting it as needed to ensure that the signal level is within an acceptable range. The present invention designs a VREF output circuit that is simultaneously universally applicable to the five standards of DDR4, DDR5, LPDDR4, LPDDR5, and LPDDR4X, based on the specifications published by JEDEC. When the VDDQ voltage is at different voltage standards of 0.3V, 0.5V, 0.6V, 1.1V, and 1.2V, and considering PVT (Process, Voltage, Temperature) variations, this design can obtain different variation ranges and different step sizes of the VREF corresponding to different protocols, as specified in the JEDEC specification.

This section is intended to provide background or context for understanding the embodiments of the present invention and is for reference only, and should not be considered as an admission by the applicant that this section belongs to the prior art disclosed before the filing date of the present invention.

### SUMMARY OF THE INVENTION

An object of the application is to provide a reference voltage output circuit that is universally applicable to different standards.

This application discloses a reference voltage output circuit, comprising:
a digital to analog converter comprising a resistor string divider, a plurality of first multiplexers and a second multiplexer, wherein a first power source terminal supplies power to the resistor string divider, the resistor string divider generates multiple bits of divided voltages based on a mode selection signal and a reference voltage control signal, the multiple bits of divided voltages are grouped and output to respective first multiplexers, outputs of all the plurality of first multiplexers are coupled to the second multiplexer, and the plurality of first multiplexers and the second multiplexer selectively output one divided voltage respectively based on the mode selection signal and a reference voltage output selection signal;
a level shift circuit, the level shift circuit is coupled to the digital to analog converter and boosts the divided voltage output by the digital to analog converter in a low power mode;
a selection module comprising a third multiplexer, wherein the third multiplexer receives the boosted divided voltage output by the level shift circuit or the divided voltage output by the digital to analog converter, and based on the mode selection signal selects either the boosted divided voltage for differential output in the low power mode or the divided voltage output by the digital to analog converter for differential output in a non-low power mode; and
an output buffer comprising a bias circuit, an operational amplifier, and an output stage circuit, wherein the bias circuit provides a bias voltage to the operational amplifier, the operational amplifier receives the differential voltages output by the selection module and performs operational amplification on the differential voltages, the output stage circuit converts the amplified differential voltages into a single ended voltage and outputs it as a reference voltage, and the reference voltage is output to the level shift circuit and the selection module.

In a preferred embodiment, the output stage circuit comprises a Class AB amplifier, the Class AB amplifier comprises a first PMOS transistor, a second PMOS transistor, a first NMOS transistor, and a second NMOS transistor, wherein gates of the first NMOS transistor and the second NMOS transistor are respectively coupled to a pair of amplified differential voltages output by the operational amplifier, sources of the first PMOS transistor and the second PMOS transistor are both coupled to a second power source terminal, a gate and a drain of the first PMOS transistor, a gate of the second PMOS transistor, and a drain of the first NMOS transistor are connected together, and a drain of the second PMOS transistor and a drain of the second NMOS transistor are connected to output the reference voltage, and sources of the first NMOS transistor and the second NMOS transistor are both coupled to a ground terminal.

In a preferred embodiment, the resistor string divider comprises first to seventh resistors with fixed resistance, an eighth resistor with adjustable resistance, and ninth to seventeenth resistors with fixed resistance, which are sequentially connected between the first power source terminal and the ground terminal, the ends of the first to seventh resistors are sequentially coupled to the first power source terminal through first to eighth switches, and the ends of the ninth to sixteenth resistors are sequentially coupled to the ground terminal through the first to eighth switches, the resistor string divider generates 128 (7-bit) of divided voltages according to the mode selection signal and the reference voltage control signal.

In a preferred embodiment, the digital to analog converter comprises eight first multiplexers, each first multiplexer sequentially receives 4 bits of divided voltage, and the first multiplexer is a 16-to-1 selector.

In a preferred embodiment, the second multiplexer receives 8 divided voltages composed of outputs of the eight first multiplexers, and the second multiplexer is an 8-to-1 selector.

In a preferred embodiment, the mode selection signal is a 3-bit digital signal, and the reference voltage control signal is a 1-bit digital signal;

when the mode selection signal is 000, a working mode of the reference voltage output circuit is DDR4, the first switch is turned on when the reference voltage control signal is 0, and the second switch is turned on when the reference voltage control signal is 1;
when the mode selection signal is 001, the working mode of the reference voltage output circuit is LPDDR4, the third switch is turned on when the reference voltage control signal is 0, and the fourth switch is turned on when the reference voltage control signal is 1;
when the mode selection signal is 010, the working mode of the reference voltage output circuit is DDR5, and the fifth switch is turned on;
when the mode selection signal is 011, the working mode of the reference voltage output circuit is LPDDR5, and the sixth switch is turned on;
when the mode selection signal is 100, the working mode of the reference voltage output circuit is LPDDR4X, the seventh switch is turned on when the reference voltage control signal is 0, and the eighth switch is turned on when the reference voltage control signal is 1.

In a preferred embodiment, the reference voltage output selection signal is a 7-bit digital signal VSEL<6:0>, and a control codeword OP<6:0> is generated based on the mode selection signal and the reference voltage output selection signal, wherein OP<3:0> controls the plurality of first multiplexers, and OP<6:4> controls the second multiplexer;
when the mode selection signal is 000, 001, 011, or 100, OP<5:0> equals VSEL<5:0>, and OP<6> is 0;
when the mode selection signal is 010, OP<5:0> equals VSELB<5:0>, OP<6> equals VSELB<6>, wherein VSELB<6:0> is the bitwise inversion of VSEL<6:0>.

In a preferred embodiment, the level shift circuit comprises a third PMOS transistor, a fourth PMOS transistor, a first resistor, and a second resistor, wherein sources of the third PMOS transistor and the fourth PMOS transistor are both coupled to a second power source terminal, a gate of the third PMOS transistor receives the divided voltage output by the digital to analog converter, a drain of the third PMOS transistor is coupled to one end of the first resistor, a gate of the fourth PMOS transistor receives the reference voltage, a drain of the fourth PMOS transistor is coupled to one end of the second resistor, and the other ends of the first resistor and the second resistor are both coupled to the ground terminal, wherein the sources of the third PMOS transistor and the fourth PMOS transistor output a pair of differential boosted divided voltages.

In a preferred embodiment, the selection module comprises two third multiplexers, wherein the third multiplexers are 2-to-1 selectors; one input terminal of one of the third multiplexers receives one of a pair of differential boosted divided voltages, and the other input terminal of said one of the third multiplexers receives the reference voltage; one input terminal of the other third multiplexer receives the other of the pair of differential boosted divided voltages, and the other input terminal of the other third multiplexer receives the divided voltage output by the digital to analog converter.

In a preferred embodiment, the two third multiplexers output based on the mode selection signal, and the mode selection signal is a 3-bit digital signal, when the mode selection signal is 000, control signals of the two third multiplexers are 1;
when the mode selection signal is 001, the control signals of the two third multiplexers are 0;
when the mode selection signal is 010, the control signals of the two third multiplexers are 1;
when the mode selection signal is 011, the control signals of the two third multiplexers are 0;
when the mode selection signal is 100, the control signals of the two third multiplexers are 0.

Compared with existing solutions, the present invention is more universally applicable, more flexible in applicable specifications, and can simultaneously support five standards of DDR4, DDR5, LPDDR4, LPDDR5, and LPDDR4X, and supports a wider variation range of the power source VDDQ. After the user sets the control codeword corresponding to the current working mode of the device, the corresponding voltage range and step size for the corresponding working mode can be obtained. Furthermore, the present invention minimizes the die area and improves the portability and reusability of the circuit by reusing the resistor string and the output buffer.

In addition, the present invention can have various usage scenarios, such as the reference voltage output circuit that only supports a single standard, or the reference voltage output circuit that supports 2-4 standards (arbitrarily selecting a single one or a combination of multiple standards), or the reference voltage output circuit that supports all five standards. The present invention has strong flexibility and adaptability in supporting circuit usage scenarios without consuming an equal proportion of circuit resources, achieving accurate output of the reference voltage.

The technical features disclosed in the above-mentioned invention content, the technical features disclosed in various embodiments and examples in the following text, and the technical features disclosed in the drawings can all be freely combined to form various new technical solutions (which should be considered as already disclosed in this specification), unless such combinations of technical features are technically infeasible. For example, if feature A+B+C is disclosed in one example and feature A+B+D+E is disclosed in another example, and features C and D are equivalent technical means that serve the same purpose, only one of them can be chosen for technical reasons and cannot be used simultaneously. Feature E can be combined with feature C from a technical perspective. Therefore, the A+B+C+D solution should not be considered as already disclosed because it is technically infeasible, while the A+B+C+E solution should be considered as already disclosed.

### BRIEF DESCRIPTION OF THE FIGURES

FIG. 1 is a block diagram of a reference voltage output circuit according to an embodiment of the present invention.

FIG. 2 is a schematic diagram of a digital to analog converter according to an embodiment of the present invention.

FIG. 3 is a schematic structural diagram of a level shift circuit, a selection circuit, and an output buffer according to an embodiment of the present invention.

FIG. 4 is a simplified equivalent circuit diagram of the reference voltage output circuit in a low power mode according to an embodiment of the present invention.

FIG. 5 is a simplified equivalent circuit diagram of the reference voltage output circuit in a normal-power mode according to an embodiment of the present invention.

FIG. 6 is a simplified equivalent circuit diagram of the DAC when the working mode is selected as DDR4 and the Range is selected as range1 according to an embodiment of the present invention.

FIG. 7 is a simplified equivalent circuit diagram of the DAC when the working mode is selected as DDR5 according to an embodiment of the present invention.

### DETAILED DESCRIPTION

In the following description, numerous technical details are set forth in order to provide the readers with a better understanding of the present invention. However, those skilled in the art can understand that the technical solutions claimed in the present invention can be implemented without these technical details and various changes and modifications based on the following embodiments.

In order to make the objects, technical solutions and advantages of the present invention clearer, embodiments of the present invention will be further described in detail below with reference to the accompanying drawings.

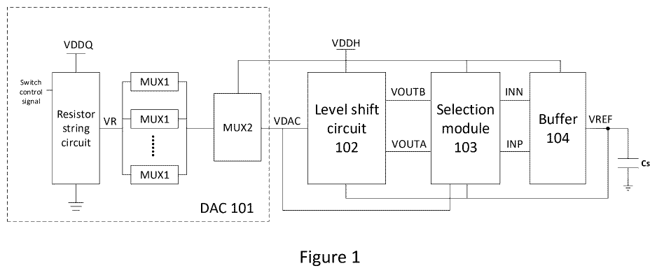

The embodiment of the present invention relates to a reference voltage output circuit, as shown in FIG. 1. The reference voltage output circuit comprises a digital to analog converter (DAC) 101, a level shift circuit 102, a selection module 103, and an output buffer (Buf) 104. The DAC 101 is configured to generate a divided voltage VDAC according to the settings, and output the divided voltage VDAC to the level shift circuit 102. The level shift circuit 102 determines whether to boost the divided voltage VDAC based on the selected mode, and outputs a pair of differential divided voltages VOUTA, VOUTB to the selection module 103. It should be noted that the level shift circuit 102 is only used in a low power mode. The selection module 103 receives the differential voltages VOUTA, VOUTB and outputs voltages INN, INP to the output buffer 104. The output buffer 104 amplifies the voltages INN, INP in the output stage, converts the differential voltages into a single ended voltage, and outputs the required reference voltage VREF.

The DAC 101 comprises a resistor string divider 105, a plurality of first multiplexers MUX1, and a second multiplexer MUX2. The resistor string divider 105 is connected between a first power terminal VDDQ and a ground terminal GND, and the first power terminal VDDQ supplies power to the resistor string divider 105. The resistor string divider 105 generates multiple bits of divided voltages VR according to a mode selection signal MODE_SEL and a reference voltage control signal, wherein a switch control signal can be obtained by logical operation on the mode selection signal MODE_SEL and the reference voltage control signal, and the switch control signal may be used to control the connection relationship of the dividing resistors in the resistor string divider 105, thereby generating corresponding divided voltages VR. The multiple bits of divided voltages are grouped and output to the respective first multiplexers MUX1. The outputs of the plurality of first multiplexers MUX1 are all coupled to the second multiplexer MUX2, and the plurality of first multiplexers MUX1 and the second multiplexer MUX2 selectively output the divided voltage VDAC based on the mode selection signal MODE_SEL and a reference voltage output selection signal.

The level shift circuit 102 is coupled to the DAC 101 and boosts the divided voltage VDAC output by the DAC 101 in the low power mode. The selection module 103 comprises a third multiplexer (not shown in the figure), which receives the boosted divided voltage output by the level shift circuit 102 or the divided voltage VDAC output by the DAC 101, and selects the boosted divided voltage to output in the low power mode or the divided voltage VDAC to output by the DAC 101 in a non-low power mode based on the mode selection signal MODE_SEL. The output buffer 104 comprises a bias circuit, an operational amplifier, and an output stage circuit. The bias circuit provides a bias voltage to the operational amplifier. The operational amplifier receives the divided voltage output by the selection module 103 and performs operational amplification on the divided voltage. The output stage circuit outputs the amplified divided voltage as the reference voltage VREF and outputs the reference voltage VREF to the level shift circuit 102 and the selection module 103. An output terminal of the output stage circuit is coupled with a voltage stabilizing capacitor Cs which is used to stabilize the VREF voltage. The output buffer 104 will be described in detail below.

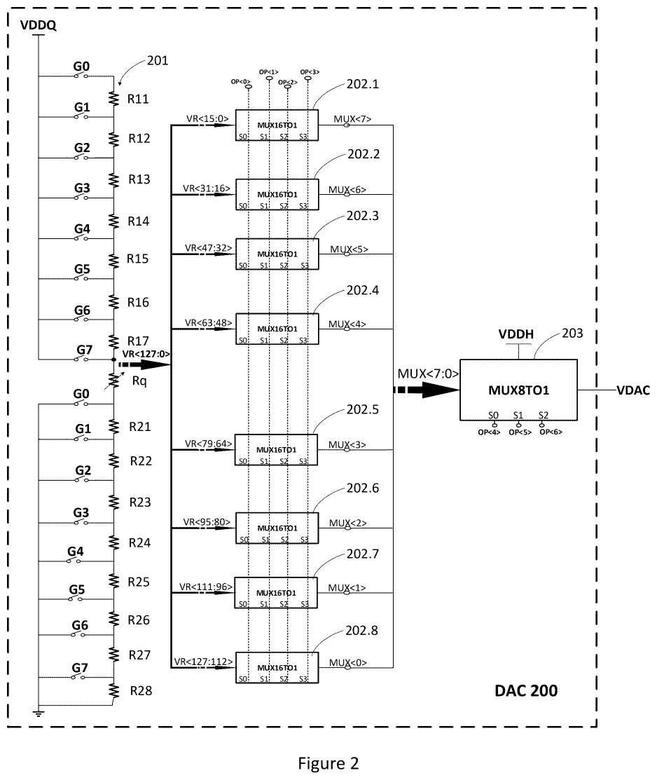

FIG. 2 is a schematic diagram of a digital to analog converter 200 according to an embodiment of the present invention. The digital to analog converter (DAC) 200 comprises a resistor string divider 201, a plurality of first multiplexers 202.1 to 202. N, and a second multiplexer 203. In this embodiment, the DAC 200 may comprise eight first multiplexers 202, that is, N is equal to 8.

The resistor string divider 202 comprises first to seventh resistors with fixed resistance R11 to R17, an eighth resistor with adjustable resistance Rq, and ninth to seventeenth resistors with fixed resistance R21 to R28, which are sequentially connected between the first power source terminal VDDQ and the ground terminal. Wherein, the resistances of the first to seventh resistors R11 to R17 may be different or the same. The resistances of the ninth to seventeenth resistors R21 to R28 may be different or the same. The ends of the first to seventh resistors R11 to R17 are sequentially coupled to the first power source terminal VDDQ through the first to eighth switches G0 to G7, that is, the first to eighth switches G0 to G7 respectively control whether the first to seventh resistors R11 to R17 are connected to the first power terminal VDDQ. The ends of the ninth to sixteenth resistors R21 to R27 are sequentially coupled to the ground terminal through the first to eighth switches G0 to G7, that is, the first to eighth switches G0 to G7 respectively control whether the ninth to sixteenth fixed resistors R21 to R27 are connected to the ground terminal. The resistor string divider 201 generates 128 (corresponding to 7 bits of) divided voltages VR<127:0>, that is, 128 divided voltages, based on the mode selection signal MODE_SEL and the reference voltage control signal RANGE. It should be noted that the first switch G0 to the eighth switch G7 in this embodiment refer to the switches that are controlled to be closed or open by a first switch control signal G0 to an eighth switch control signal G7, that is to say, the first switch G0 is controlled to closed or open by the first switch control signal G0, the second switch G1 is controlled to closed or open by the second switch control signal G1, and so on. Therefore, the first resistor R11 and the ninth resistor R21 are controlled by the same logic, the second resistor R12 and the tenth resistor R22 are controlled by the same logic, and so on.

Continuing to refer to FIG. 2, the DAC 200 comprises eight first multiplexers 202.1 to 202.8, and the 128 (corresponding to 7 bits of) divided voltages VR<127:0> are grouped and output to the corresponding first multiplexers. Specifically, each first multiplexer sequentially receives 4 bits of divided voltages (i.e., 16 voltages). For example, the 4 bits of divided voltages are sequentially output to the corresponding first multiplexers 202.1 to 202.8 in the order from the low bit to the high bit. Specifically, the first multiplexer 202.1 receives the divided voltages VR<15:0>, the first multiplexer 202.2 receives the divided voltages VR<31:16>, and so on. In one embodiment, the first multiplexers 202.1 to 202.8 are all 16-to-1 selectors (MUX16TO1). Each of the first multiplexers 202.1 to 202.8 outputs one divided voltage according to the selection signal OP<1:3>. For example, MUX<7> to MUX<0> are output in the order from the low bit to the high bit, forming 8 (corresponding to 3 bits of) divided voltages MUX<7:0>.

In one embodiment, the second multiplexer 203 receives the 8 (corresponding to 3 bits of) divided voltages MUX<7:0> composed of the outputs of the eight first multiplexers 202.1 to 202.8, the second multiplexer 203 outputs one divided voltage, which is the final divided voltage VDAC, according to the selection signal OP<4:6>. In one embodiment, the second multiplexer 203 is an 8-to-1 selector (MUX8TO1).

In one embodiment, the mode selection signal MODE_SEL<2:0> is a 3-bit digital signal, and the reference voltage control signal RANGE is a 1-bit digital signal,

When the mode selection signal MODE_SEL<2:0> is 000, the working mode of the reference voltage output circuit is DDR4, and the first switch G0 is turned on when the reference voltage control signal RANGE is 0 and the second switch G2 is turned on when the reference voltage control signal RANGE is 1. When the mode selection signal MODE_SEL<2:0> is 001, the working mode of the reference voltage output circuit is LPDDR4, and the third switch G3 is turned on when the reference voltage control signal RANGE is 0 and the fourth switch G4 is turned on when the reference voltage control signal RANGE is 1. When the mode selection signal MODE_SEL<2:0> is 010, the working mode of the reference voltage output circuit is DDR5, and the fifth switch G5 is turned on. When the mode selection signal MODE_SEL<2:0> is 011, the working mode of the reference voltage output circuit is LPDDR5, and the sixth switch G6 is turned on. When the mode selection signal MODE_SEL<2:0> is 100, the working mode of the reference voltage output circuit is LPDDR4X, the seventh switch G6 is turned on when the reference voltage control signal RANGE is 0 and the eighth switch G7 is turned on when the reference voltage control signal RANGE is 1.

In one embodiment, the reference voltage output selection signal is a 7-bit digital signal VSEL<6:0>, and a control codeword OP<6:0> is generated based on the mode selection signal MODE_SEL<2:0> and the reference voltage output selection signal VSEL<6:0>, wherein OP<3:0> controls the plurality of first multiplexers 202.1 to 202.8, and OP<6:4> controls the second multiplexer 203. When the mode selection signal MODE_SEL<2:0> is 000, 001, 011, 100, OP<5:0> equals VSEL<5:0>, and OP<6> is 0. When the mode selection signal MODE_SEL<2:0> is 010, OP<5:0> equals VSELB<5:0>, OP<6> equals VSELB<6>, wherein VSELB<6:0> is the bitwise inversion of VSEL<6:0>.

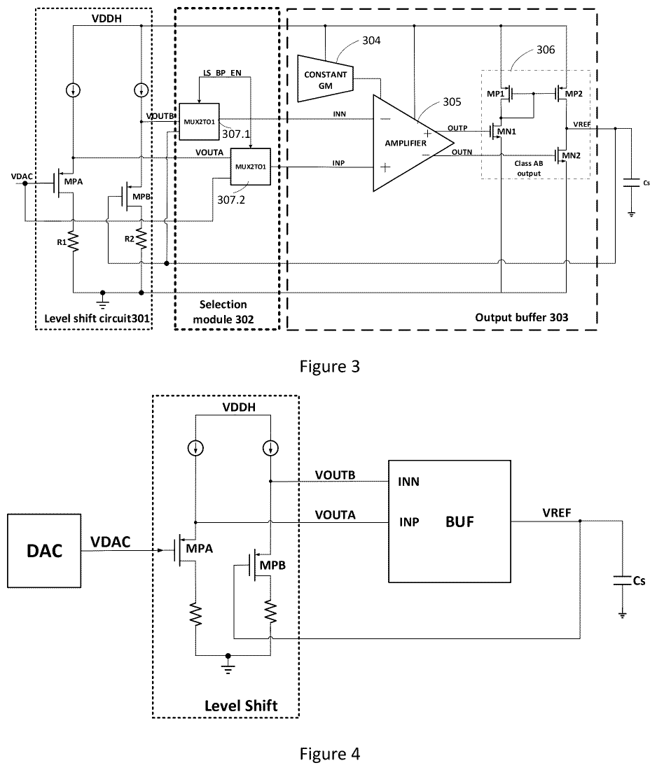

FIG. 3 shows a schematic diagram of the output buffer 303. The output buffer 303 comprises a bias circuit (CONSTANT GM) 304, an operational amplifier (AMPLIFIER) 305, and an output stage circuit 306. The output stage circuit 306 comprises a Class AB amplifier, which comprises a first PMOS transistor MP1, a second PMOS transistor MP2, a first NMOS transistor MN1, and a second NMOS transistor MN2. Gates of the first NMOS transistor MN1 and the second NMOS transistor MN2 are respectively coupled to a pair of differential amplified divided voltages OUTP, OUTN output by the operational amplifier 305. Sources of the first PMOS transistor MP1 and the second PMOS transistor MP2 are both coupled to the second power source terminal VDDH. A gate and a drain of the first PMOS transistor MP1, a gate of the second PMOS transistor MP2, and a drain of the first NMOS transistor MN1 are connected. A drain of the second PMOS transistor MP2 and a drain of the second NMOS transistor MN2 are connected together and output the reference voltage VREF. Sources of the first NMOS transistor MN1 and the second NMOS transistor MN2 are both coupled to the ground terminal.

Continuing to refer to FIG. 3, the level shift circuit 301 comprises a third PMOS transistor MPA, a fourth PMOS transistor MPB, a first resistor R1, and a second resistor R2. Sources of the third PMOS transistor MPA and the fourth PMOS transistor MPB are both coupled to the second power source terminal VDDH, a gate of the third PMOS transistor MPA receives the divided voltage VDAC output by the digital to analog converter, a drain of the third PMOS transistor MPA is coupled to one end of the first resistor R1, a gate of the fourth PMOS transistor MPB receives the reference voltage VREF, a drain of the fourth PMOS transistor MPB is coupled to one end of the second resistor R2, and the other ends of the first resistor R1 and the second resistor R2 are both coupled to the ground terminal. Sources of the third PMOS transistor MPA and the fourth PMOS transistor MPB respectively output a pair of differential boosted divided voltages VOUTA, VOUTB.

Furthermore, the selection module 302 comprises two third multiplexers 307.1, 307.2, both of which are 2-to-1 selectors (MUX2TO1). One input terminal of the third multiplexer 307.1 receives one divided voltage VOUTB of the pair of differential boosted divided voltages, while the other input of the third multiplexer 307.1 receives the reference voltage VREF. One input terminal of the other third multiplexer 307.2 receives the other divided voltage VOUTA of the pair of differential boosted divided voltages, and the other input terminal of the other third multiplexer 307.2 receives the divided voltage VDAC output by the digital to analog converter.

In one embodiment, two third multiplexers 307.1, 307.2 output based on a mode selection signal, which is a 3-bit digital signal MODE_SEL<2:0>. When the mode selection signal MODE_SEL<2:0> is 000, the control signals of the two third multiplexers 307.1, 307.2 are 1; When the mode selection signal MODE_SEL<2:0> is 001, the control signals of the two third multiplexers 307.1, 307.2 are 0; When the mode selection signal MODE_SEL<2:0> is 010, the control signals of the two third multiplexers 307.1, 307.2 are 1; When the mode selection signal MODE_SEL<2:0> is 011, the control signals of the two third multiplexers 307.1, 307.2 are 0; When the mode selection signal MODE_SEL<2:0> is 100, the control signals of the two third multiplexers 307.1, 307.2 are 0.

The present invention proposes a reference voltage output circuit that simultaneously supports the five standards of DDR4, DDR5, LPDDR4, LPDDR5, and LPDDR4X, which is more universally applicable, more flexible in applicable specifications, and supports a wider variation range of the power source VDDQ. After the user sets the control codeword corresponding to the current working mode of the device (for example, the mode selection signal MODE_SEL<2:0>, the reference voltage control signal RANGE, and the reference voltage output selection signal VSEL<6:0>), the corresponding working mode, the corresponding voltage range, and the step size can be obtained. Furthermore, the present invention minimizes the die area and improves the portability and reusability of the circuit by reusing the resistor string and the output buffer.

In order to better understand the technical solution of the present invention, a specific example is described below. The details listed in this example are mainly for ease of understanding and should not be construed as limiting the protection scope of the present invention.

Referring to FIGS. 1 to 3, the top-level structure of the reference voltage output circuit mainly consists of four sub-modules: a DAC, a level shift circuit, a selection module, and an output buffer. In the top-level overall circuit, only the resistor string divider in the DAC is powered by VDDQ, while all other modules, including MUX16TO1, MUX8TO1, the level shift circuit, the selection module, and the output buffer, are supplied by VDDH. This approach not only realizes the reference voltage output that supports a wider range of the power source VDDQ (0.3V, 0.5V, 0.6V, 1.1V, 1.2V) under different standards, but also reduces the design difficulty of other module circuits, because VDDH is a fixed power source that only changes by +10% under PVT.

The DAC sub-module outputs different VDAC voltages by logically controlling the voltage division ratio of the resistor string. Different control codewords can selectively turn on the switches G0-G7. The resistor strings R11-R17, R21-R28 are resistors with fixed resistance values, and Rq is a resistor with adjustable resistance value. The on/off signals of G0˜G7 are controlled by the mode selection signal (MODE_SEL) and the VREF reference voltage control signal (RANGE). The truth table is shown in Table 1 below:

TABLE 1
Truth Table of switch control signal Switch_Cate_Open

| MODE_SEL<2:0> | Working mode | RANGE | VREF Range | Switch_Gate_Open |
|---|---|---|---|---|
| 000 | DDR4 | 0 | range1 | G0 |
| | | 1 | range2 | G1 |
| 001 | LPDDR4 | 0 | range1 | G2 |
| | | 1 | range2 | G3 |
| 010 | DDR5 | / | / | G4 |
| 011 | LPDDR5 | / | / | G5 |
| 100 | LPDDR4X | 0 | range1 | G6 |
| | | 1 | range2 | G7 |

| | |
|---|---|
| Others | reserved |

It should be noted that in the definitions of DDR5 JESD79-5 and LPDDR5 JESD209-5B standard specifications, the output reference voltage VREF is a continuous full range, so the output range of the reference voltage VREF is independent of the control codeword VREF Range under these two standard protocols. When the control codeword RANGE is 0, range1 is selected accordingly, and when the control codeword RANGE is 1, range2 is selected accordingly.

OP<3:0> is the select control signal for MUX16TO1, and OP<6:4> is the select control signal for MUX8TO1. The 7-bit control codeword OP<6:0> is obtained by logical operation of the VREF output selection signal VSEL<6:0> and the working mode selection signal MODE_SEL<2:0>. The truth table is shown in Table 2 below:

TABLE 2
Truth table of the select control signal OP<6:0>

| MODE_SEL<2:0> | Working mode | RE_EN1 | 6 | OP<5:0> |
|---|---|---|---|---|
| 000 | DDR4 | 0 | 0 | VSEL<5:0> |
| 001 | LPDDR4 | 0 | 0 | VSEL<5:0> |
| 010 | DDR5 | 1 | VSELB<6> | VSELB<5:0> |
| 011 | LPDDR5 | 0 | 0 | VSEL<5:0> |
| 100 | LPDDR4X | 0 | 0 | VSEL<5:0> |

| | |
|---|---|
| Others | reserved |

Where RE_EN is an intermediate signal used to flag whether the output range of the reference voltage VREF should be flipped. This is because the present invention considers that in the DDR5 JESD79-5 standard specification, the output range of the reference voltage VREF is from 97.5% to 35% (decreasing), while the output ranges of the reference voltage VREF of other modes (e.g., DDR4, LPDDR4, LPDDR5, LPDDR4X) are increasing. Therefore, only when the working mode is selected as DDR5 and the RE_EN flag bit is high, the output range can smoothly achieve reverse/decremental output.

The voltage value of VDDQ is different under different standard specifications. The specific values can be referred to in Table 3 below:

TABLE 3
Corresponding values and ranges of the power source
VDDQ under different standard specifications

| Symbol | | LPDDR4 | LPDDR5 | | DDR4 | DDR5 | LPDDR4X |
|---|---|---|---|---|---|---|---|
| VDDQ | / | / | range-1 | range-2 | / | / | / |
| | Minimum value | 1.06 | 0.47 | 0.27 | 1.14 | 1.067 | 0.57 |
| | Min | | | | | | |
| | Typical value Typ | 1.1 | 0.5 | 0.3 | 1.2 | 1.1 | 0.6 |
| | Maximum value | 1.17 | 0.57 | 0.37 | 1.26 | 1.166 | 0.65 |
| | Max | | | | | | |

Obviously, when the working mode is LPDDR4, LPDDR5, or LPDDR4X (i.e., the low power mode), the power source VDDQ is often relatively low, so the VDAC value obtained by the DAC module through resistor division on the VDDQ is also lower. In order for the operational amplifier to still function properly when VDAC is input to the operational amplifier module in the low power mode, the VDAC voltage needs to be boosted.

In the present invention, the level shift module is used to boost the lower voltage VDAC and the feedback voltage VREF by a fixed gate-source voltage value, and then the boosted voltage values (VOUTA and VOUTB) are selected through the selection module and used as the inputs INP and INN of the operational amplifier respectively. The simplified equivalent circuit is shown in FIG. 4.

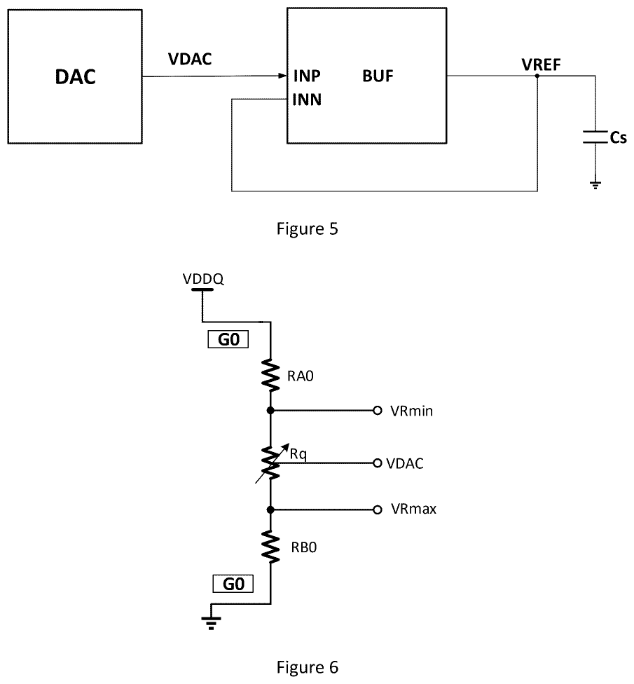

When the working mode is DDR4 or DDR5 (i.e., normal-power mode), the VDAC voltage does not need to be boosted. At this time, the selection module selects VDAC, VREF as the inputs INP and INN of the operational amplifier, respectively, that is, the level shift module is bypassed at this time. The simplified equivalent circuit is shown in FIG. 5.

The selection signal LS_BP_EN in the selection module can be realized through logical operation on the mode selection signal MODE_SEL<2:0>, or through other methods. Table 4 shows the truth table corresponding to the implementation of the present invention.

TABLE 4
Truth table for the selection signal LS_BP_EN

| MODE_SEL<2:0> | Working mode | LS_BP_EN |
|---|---|---|
| 000 | DDR4 | 1 |
| 001 | LPDDR4 | 0 |
| 010 | DDR5 | 1 |
| 011 | LPDDR5 | 0 |
| 100 | LPDDR4X | 0 |

The buffer module consists of three parts: a bias circuit CONSTANT GM, an operational amplification circuit AMPLIFIER, and an output stage circuit Class AB output. The Class AB output structure can achieve better load capacity and a rail-to-rail output voltage range, providing better support for different VREF outputs in different working modes.

FIG. 6 shows the equivalent circuit diagram of the DAC when the working mode is DDR4 and the range selection is range1 (i.e., the mode selection signal is 000 and RANGE is 0) in one embodiment, where the switch control signal Switch_Cate_Open selects G0 to turn on. The range of the VDAC output by the DAC is between the minimum value VRmin and the maximum value VRmax, and depends on the value of OP<5:0>. VRmax and VRmin are obtained by the following formulas, where RA0 is the equivalent resistance of R¹¹ to R17, RB0 is the equivalent resistance of R21 to R28, and Rq_min and Rq_max are respectively the minimum and maximum values of the adjustable resistor Ra.

$$V {R}_{m ax} = \frac{R B 0 - Rq\_min}{R B 0 - R A 0}$$

$$V {R}_{m i n} = \frac{R B 0 - Rq\_max}{R B 0 - R A 0}$$

It should be noted that LPDDR4, LPDDR5, and LPDDRX can use the same formula mentioned above to calculate the output range of VDAC.

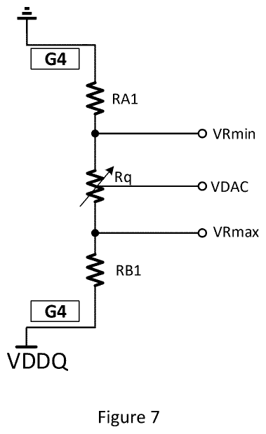

FIG. 7 shows the equivalent circuit diagram of the DAC when the working mode is DDR5 (i.e., the mode selection signal is 010) in one embodiment, where the switch control signal Switch_Cate_Open selects G4 to turn on.

The range of the VDAC output by the DAC is between the minimum value VRmin and the maximum value VRmax, and depends on the value of OP<5:0>. VRmax and VRmin are obtained by the following formulas, where RA1 is the equivalent resistance of R11 to R17, RB1 is the equivalent resistance of R21 to R28, and Rq_min and Rq_max are respectively the minimum and maximum values of the adjustable resistor Rq.

$$V {R}_{ma x} = \frac{Rq\_max - R A 1}{R B 1 - R A 1}$$

$$V {R}_{m i n} = \frac{Rq\_min - R A 1}{R B 1 - R A 1}$$

The above embodiments describe a reference voltage circuit that simultaneously supports five standards. However, the present invention can also have various usage scenarios, such as a reference voltage VREF that only supports a single standard, or a reference voltage VREF that supports 2-4 standards (arbitrarily selecting a single one or a combination of multiple standards). For the situation of satisfying only a single protocol, the switch control signal Switch_Cate_Open may be fixed as a single selection signal, depending on the specific protocol type to be supported, the 16-to-1 selector MUX16TO1 in the DAC may be replaced with a 4-to-1 selector MUX4TO1, and the 8-to-1 selector MUX8TO1 may be replaced with a 2-to-1 selector MUX2TO1. For the situation of satisfying two protocols, the switch control signal Switch_Cate_Open may be fixed as a binary selection signal, depending on the specific protocol type to be supported, the 16-to-1 selector MUX16TO1 in the DAC may be replaced with an 8-to-1 selector MUX8TO1, and the 8-to-1 selector MUX8TO1 may be replaced with a 4-to-1 selector MUX2TO1. The present invention has strong flexibility and adaptability in supporting circuit usage scenarios without consuming an equal proportion of circuit resources, achieving accurate output of the reference voltage.

It should be noted that in this specification, relational terms such as the first and second are only configured to distinguish one entity or operation from another entity or operation, and do not necessarily require or imply any such actual relationship or order between these entities or operations. Furthermore, the term “comprises” or “comprising” or “includes” or any other variations thereof is intended to encompass a non-exclusive inclusion, such that a process, method, article, or device that comprises a multiple elements includes not only those elements but also other elements, or elements that are inherent to such a process, method, article, or device. Without more restrictions, the element defined by the phrase “comprise(s) a/an” does not exclude that there are other identical elements in the process, method, article or device that includes the element. In this specification, if it is mentioned that an action is performed according to an element, it means the meaning of performing the action at least according to the element, and includes two cases: the action is performed only on the basis of the element, and the action is performed based on the element and other elements. Multiple, repeatedly, various, etc., expressions include 2, twice, 2 types, and 2 or more, twice or more, and 2 types or more types.

The term “coupled to” and its derivatives may be used herein. “Coupled” may mean that two or more elements are in direct physical or electrical contact. However, “coupled” may also mean that two or more elements are in indirect contact with each other, but still cooperate or interact with each other, and may mean that one or more other elements are coupled or connected between the elements referred to as being coupled to each other.

The specification includes combinations of the various embodiments described herein. Separate references to embodiments (such as “an embodiment” or “some embodiments” or “preferred embodiments”) do not necessarily refer to the same embodiment. However, these embodiments are not mutually exclusive unless indicated as mutually exclusive or clearly mutually exclusive by those skilled in the art. It should be noted that unless the context clearly indicates or requires otherwise, the word “or” is used in this specification in a non-exclusive sense.

All documents mentioned in this specification are considered to be included in the disclosure of the application as a whole, so that they can be used as a basis for modification when necessary. In addition, it should be understood that the above descriptions are only preferred embodiments of this specification, and are not intended to limit the protection scope of this specification. Any modification, equivalent replacement, improvement, etc. made within the spirit and principle of one or more embodiments of this specification should be included in the protection scope of one or more embodiments of this specification.

What is claimed is:

1. A reference voltage output circuit, comprising:
a digital to analog converter comprising a resistor string divider, a plurality of first multiplexers and a second multiplexer, wherein a first power source terminal supplies power to the resistor string divider, the resistor string divider generates multiple bits of divided voltages based on a mode selection signal and a reference voltage control signal, the multiple bits of divided voltages are grouped and output to respective first multiplexers, outputs of all the plurality of first multiplexers are coupled to the second multiplexer, and the plurality of first multiplexers and the second multiplexer selectively output one divided voltage respectively based on the mode selection signal and a reference voltage output selection signal;
a level shift circuit, the level shift circuit is coupled to the digital to analog converter and boosts the divided voltage output by the digital to analog converter in a low power mode;
a selection module comprising a third multiplexer, wherein the third multiplexer receives the boosted divided voltage output by the level shift circuit or the divided voltage output by the digital to analog converter, and based on the mode selection signal selects either the boosted divided voltage for differential output in the low power mode or the divided voltage output by the digital to analog converter for differential output in a non-low power mode; and
an output buffer comprising a bias circuit, an operational amplifier, and an output stage circuit, wherein the bias circuit provides a bias voltage to the operational amplifier, the operational amplifier receives the differential voltages output by the selection module and amplifies the differential voltages, the output stage circuit converts the amplified differential voltages into a single ended voltage and outputs it as a reference voltage, and the reference voltage is output to the level shift circuit and the selection module.

2. The reference voltage output circuit of claim 1, wherein the output stage circuit comprises a Class AB amplifier, the Class AB amplifier comprises a first PMOS transistor, a second PMOS transistor, a first NMOS transistor, and a second NMOS transistor, wherein gates of the first NMOS transistor and the second NMOS transistor are respectively coupled to a pair of amplified differential voltages output by the operational amplifier, sources of the first PMOS transistor and the second PMOS transistor are both coupled to a second power source terminal, a gate and a drain of the first PMOS transistor, a gate of the second PMOS transistor, and a drain of the first NMOS transistor are connected together, and a drain of the second PMOS transistor and a drain of the second NMOS transistor are connected to output the reference voltage, and sources of the first NMOS transistor and the second NMOS transistor are both coupled to a ground terminal.

3. The reference voltage output circuit of claim 1, wherein the resistor string divider comprises first to seventh resistors with fixed resistance, an eighth resistor with adjustable resistance, and ninth to seventeenth resistors with fixed resistance, which are sequentially connected between the first power source terminal and the ground terminal, the ends of the first to seventh resistors are sequentially coupled to the first power source terminal through first to eighth switches, and the ends of the ninth to sixteenth resistors are sequentially coupled to the ground terminal through the first to eighth switches, the resistor string divider generates 7 bits of divided voltages according to the mode selection signal and the reference voltage control signal.

4. The reference voltage output circuit of claim 3, wherein the digital to analog converter comprises eight first multiplexers, each first multiplexer sequentially receives 4 bits of divided voltage, and the first multiplexer is a 16-to-1 selector.

5. The reference voltage output circuit of claim 4, wherein the second multiplexer receives 8 divided voltages composed of outputs of the eight first multiplexers, and the second multiplexer is an 8-to-1 selector.

6. The reference voltage output circuit of claim 3, wherein the mode selection signal is a 3-bit digital signal, and the reference voltage control signal is a 1-bit digital signal;
when the mode selection signal is 000, a working mode of the reference voltage output circuit is DDR4, the first switch is turned on when the reference voltage control signal is 0, and the second switch is turned on when the reference voltage control signal is 1;
when the mode selection signal is 001, the working mode of the reference voltage output circuit is LPDDR4, the third switch is turned on when the reference voltage control signal is 0, and the fourth switch is turned on when the reference voltage control signal is 1;
when the mode selection signal is 010, the working mode of the reference voltage output circuit is DDR5, and the fifth switch is turned on;
when the mode selection signal is 011, the working mode of the reference voltage output circuit is LPDDR5, and the sixth switch is turned on;
when the mode selection signal is 100, the working mode of the reference voltage output circuit is LPDDR4X, the seventh switch is turned on when the reference voltage control signal is 0, and the eighth switch is turned on when the reference voltage control signal is 1.

7. The reference voltage output circuit of claim 1, wherein the reference voltage output selection signal is a 7-bit digital signal VSEL<6:0>, and a control codeword OP<6:0> is generated based on the mode selection signal and the reference voltage output selection signal, wherein OP<3:0> controls the plurality of first multiplexers, and OP<6:4> controls the second multiplexer;
when the mode selection signal is 000, 001, 011, or 100, OP<5:0> equals VSEL<5:0>, and OP<6> is 0;
when the mode selection signal is 010, OP<5:0> equals VSELB<5:0>, OP<6> equals VSELB<6>, wherein VSELB<6:0> is the bitwise inversion of VSEL<6:0>.

8. The reference voltage output circuit of claim 1, wherein the level shift circuit comprises a third PMOS transistor, a fourth PMOS transistor, a first resistor, and a second resistor, wherein sources of the third PMOS transistor and the fourth PMOS transistor are both coupled to a second power source terminal, a gate of the third PMOS transistor receives the divided voltage output by the digital to analog converter, a drain of the third PMOS transistor is coupled to one end of the first resistor, a gate of the fourth PMOS transistor receives the reference voltage, a drain of the fourth PMOS transistor is coupled to one end of the second resistor, and the other ends of the first resistor and the second resistor are both coupled to the ground terminal, wherein the sources of the third PMOS transistor and the fourth PMOS transistor output a pair of differential boosted divided voltages.

9. The reference voltage output circuit of claim 1, wherein the selection module comprises two third multiplexers, wherein the third multiplexers are 2-to-1 selectors; one input terminal of one of the third multiplexers receives one of a pair of differential boosted divided voltages, and the other input terminal of said one of the third multiplexers receives the reference voltage; one input terminal of the other third multiplexer receives the other of the pair of differential boosted divided voltages, and the other input terminal of the other third multiplexer receives the divided voltage output by the digital to analog converter.

10. The reference voltage output circuit of claim 9, wherein the two third multiplexers output based on the mode selection signal, and the mode selection signal is a 3-bit digital signal,
when the mode selection signal is 000, control signals of the two third multiplexers are 1;
when the mode selection signal is 001, the control signals of the two third multiplexers are 0;
when the mode selection signal is 010, the control signals of the two third multiplexers are 1;
when the mode selection signal is 011, the control signals of the two third multiplexers are 0;
when the mode selection signal is 100, the control signals of the two third multiplexers are 0.
